(19) United States
(12) Patent Application Publication
(10) Pub. No.: US 2022/0165764 A1
(43) Pub. Date: May 26, 2022

(54) X-RAY FLAT PANEL DETECTOR, METHOD FOR MANUFACTURING X-RAY FLAT PANEL DETECTOR, DETECTION DEVICE AND IMAGING SYSTEM

(71) Applicant: BOE Technology Group Co., Ltd., Beijing (CN)

(72) Inventors: Jiangbo CHEN, Beijing (CN); Yao LU, Beijing (CN); Liye DUAN, Beijing (CN); Tuo SUN, Beijing (CN)

(21) Appl. No.: 17/516,206

(22) Filed: Nov. 1, 2021

(30) Foreign Application Priority Data
Nov. 20, 2020 (CN) 202011311373.2

(51) Int. Cl. H01L 27/146; H01L 27/28; G01T 1/20

(52) U.S. Cl. CPC H01L 27/14603; H01L 27/281; H01L 27/286; H01L 27/14658; H01L 27/14692; G01T 1/20184; H01L 27/14612

(57) ABSTRACT

An X-ray flat panel detector, a method for manufacturing the X-ray flat panel detector, a detection device and an imaging system are provided. The X-ray flat panel detector includes: a substrate; a back plate layer arranged on the substrate and including a plurality of thin film transistors, each thin film transistor including a source/drain electrode layer; a wiring layer arranged at a side of the back plate layer distal to the substrate and including a plurality of connection lines; and a photosensitive element layer arranged at a side of the wiring layer distal to the substrate and including first electrodes. Each first electrode is electrically connected to the source/drain electrode layer of a corresponding thin film transistor through a corresponding connection line, and an orthogonal projection of the first electrode onto the substrate does not overlap an orthogonal projection of the corresponding thin film transistor onto the substrate.

### CROSS-REFERENCE TO RELATED APPLICATION

This application claims a priority of the Chinese patent application No. 202011311373.2 filed in China on Nov. 20, 2020, which is incorporated herein by reference in its entirety.

### TECHNICAL FIELD

The present disclosure relates to the field of detection technology, in particular to an X-ray flat panel detector, a method for manufacturing the X-ray flat panel detector, a detection device and an imaging system.

### BACKGROUND

Digital Radiography (DR) is a new X-ray photographic technique developed in the 1990s, and it becomes a leading direction of the X-ray photographic technique and has been recognized by clinical organizations and imaging specialists all over the world due to such significant advantages as higher imaging speed, more convenient operation and higher image resolution. As a DR technical core, a flat panel detector is a precise and valuable device, and plays a decisive role in imaging quality. In the related art, the flat panel detectors mainly include two types, one for indirect detection and one for direct detection.

In the related art, the indirect X-ray flat panel detector mainly includes a substrate, and thin film transistors, photodiodes and a scintillation layer arranged at a side of the substrate one on another. The scintillation layer is configured to convert an X-ray into visible light, each photodiode is configured to convert the visible light into charge carriers and store them, and each thin film transistor serves as a switch. The thin film transistors are turned on progressively under the control of an external scanning control circuitry, so as to read the charge carriers stored in the photodiode and transmit them to a data processing circuitry.

However, it is found that, in the current X-ray flat panel detector, the photodiode is arranged parallel to the thin film transistor, the photodiode is arranged at a pixel region, and a filling rate is restrained by a size of the thin film transistor and a metal line, so a resolution of the X-ray flat panel detector is adversely affected. In addition, in the related art, it is impossible for a back plate with large-size pixels to be compatible with photodiodes with different sizes, so the manufacture cost may increase.

### SUMMARY

An object of the present disclosure is to provide an X-ray flat panel detector, a method for manufacturing the X-ray flat panel detector, a detection device and an imaging system.

In one aspect, the present disclosure provides in some embodiments an X-ray flat panel detector, including:

a substrate;

a back plate layer arranged on the substrate and including a plurality of thin film transistors, each of the thin film transistors including a source/drain electrode layer;

a wiring layer arranged at a side of the back plate layer distal to the substrate and including a plurality of connection lines; and

a photosensitive element layer arranged at a side of the wiring layer distal to the substrate and including a plurality of first electrodes,

wherein each of the first electrodes is electrically connected to the source/drain electrode layer of a respective one of the thin film transistors through a respective one of the connection lines, and an orthogonal projection of the first electrode onto the substrate does not overlap an orthogonal projection of the respective thin film transistor onto the substrate.

In a possible embodiment of the present disclosure, an area of an orthogonal projection of the photosensitive element layer onto the substrate is smaller than an area of an orthogonal projection of the back plate layer onto the substrate.

In a possible embodiment of the present disclosure, the back plate layer includes a passivation layer;

the passivation layer is arranged at a side of the thin film transistor distal to the substrate and covers the substrate, a plurality of first via-holes is formed in the passivation layer and penetrates through the passivation layer, each of the first via-holes exposes a source electrode or a drain electrode of a respective one of the thin film transistors;

each of the connection lines is electrically connected to a source electrode or a drain electrode of a respective one of the thin film transistor through the respective first via-hole.

In a possible embodiment of the present disclosure, the wiring layer includes a planarization layer, the planarization layer is arranged at a side of the photosensitive element layer proximate to the substrate and covers the connection lines, a plurality of second via-holes is formed in the planarization layer at predetermined positions and penetrates through the planarization layer;

each of the first electrodes is electrically connected to a respective one of the connection lines through a respective one of the second via-hole.

In a possible embodiment of the present disclosure, the photosensitive element layer includes a photodiode and a second electrode;

the photodiode is arranged at a side of the first electrode distal to the substrate;

the second electrode is arranged at a side of the photodiode distal to the first electrode.

In a possible embodiment of the present disclosure, the first electrode is a bar-shaped electrode, and the second electrode is a planar electrode; or

the first electrode is a bar-shaped electrode, the second electrode is a bar-shaped electrode, and an orthogonal projection of the second electrode onto the substrate covers an orthogonal projection of the first electrode onto the substrate.

In a possible embodiment of the present disclosure, the X-ray flat panel detector further includes a protection layer, wherein the protection layer is arranged at a side of the photosensitive element layer distal to the substrate and covers the substrate;

an area of an orthogonal projection of the protection layer onto the substrate is greater than an area of the orthogonal projection of the photosensitive element layer onto the substrate.

In another aspect, the present disclosure provides in some embodiments an X-ray flat panel detection device, including a plurality of the above-mentioned X-ray flat panel detectors arranged in an array form. Adjacent X-ray flat panel detectors are spliced with each other, and the photosensitive element layer is arranged proximate to a position where the adjacent X-ray flat panel detectors are spliced.

In yet another aspect, the present disclosure provides in some embodiments an X-ray imaging system, including the above-mentioned X-ray flat panel detector or X-ray flat panel detection device.

In still yet another aspect, the present disclosure provides in some embodiments a method for manufacturing an X-ray flat panel detector, including:

providing a substrate, and forming a back plate layer on the substrate through a patterning process, wherein the back plate layer includes thin film transistors and a passivation layer;

forming a plurality of connection lines at a side of the back plate layer distal to the substrate through a patterning process, wherein each of the connection lines is electrically connected to a source electrode or a drain electrode of a respective one of the thin film transistors through a respective first via-hole, the first via-hole penetrates through the passivation layer;

forming a planarization layer at a side of the connection line distal to the substrate through a patterning process; and forming a photosensitive element layer at a side of the planarization layer distal to the substrate through a patterning process,

wherein the photosensitive element layer includes a plurality of first electrodes, each of the first electrodes is electrically connected to a respective one of the connection lines through a respective second via-hole, the second via-hole penetrates through the planarization layer, and an orthogonal projection of the first electrode onto the substrate does not overlap an orthogonal projection of a thin film transistor whose source electrode or drain electrode is electrically connected to the first electrode onto the substrate.

In a possible embodiment of the present disclosure, the forming the back plate layer on the substrate through the patterning process includes:

forming a buffer layer on the substrate;

forming a gate electrode, a gate insulation layer, an active layer, a source electrode and a drain electrode sequentially on the buffer layer through a patterning process; and

forming the passivation layer on the source electrode and the drain electrode through a patterning process.

In a possible embodiment of the present disclosure, the forming the plurality of connection lines at the side of the back plate layer distal to the substrate through the patterning process includes:

depositing a metal layer on the passivation layer; and

patterning the metal layer to form the plurality of connection lines,

wherein an orthogonal projection of each of the connection lines onto the substrate covers an orthogonal projection of the first via-hole onto the substrate and an orthogonal projection of the second via-hole onto the substrate.

In a possible embodiment of the present disclosure, the forming the photosensitive element layer at the side of the planarization layer distal to the substrate through the patterning process includes:

forming the plurality of first electrodes on the planarization layer through a patterning process, wherein each of the first electrodes is electrically connected to a respective one of the connection lines through the respective second via-hole penetrating through the planarization layer;

forming a photodiode on the first electrode through a patterning process;

forming a second electrode on each photodiode through a patterning process.

The above description is merely an overview of the schemes in the embodiments of the present disclosure, and the schemes may be implemented in accordance with contents involved in the description so as to enable a person skilled in the art to understand the technical means of the present disclosure in a clearer manner. In order to make the objects, the technical solutions and the advantages of the present disclosure more apparent, the present disclosure will be described hereinafter in a clear manner in conjunction with the drawings and embodiments.

### BRIEF DESCRIPTION OF THE DRAWINGS

Through reading the detailed description hereinafter, the other advantages and benefits will be apparent to a person skilled in the art. The drawings are merely used to show the preferred embodiments, but shall not be construed as limiting the present disclosure. In addition, in the drawings, same reference symbols represent same members. In these drawings,

FIG. 1 is a schematic view of a X-ray flat panel detector in related art;

FIG. 2 is a schematic view of an X-ray flat panel detector according to an embodiment of the present disclosure;

FIG. 3 is a schematic view showing first via-holes in a back plate layer according to an embodiment of the present disclosure;

FIG. 4 is a schematic view showing second via-holes in a photosensitive element layer according to an embodiment of the present disclosure;

FIG. 5 is a schematic view showing a situation where the back plate layer is connected to the photosensitive element layer according to an embodiment of the present disclosure;

FIG. 6 is a schematic view showing a splicing structure of the photosensitive element layer according to an embodiment of the present disclosure;

FIG. 7 is a schematic view showing a situation where adjacent X-ray flat panel detectors are spliced with each other according to an embodiment of the present disclosure;

FIG. 8 is a flow chart of a method for manufacturing the X-ray flat panel detector according to an embodiment of the present disclosure; and

FIG. 9 is another schematic view of the X-ray flat panel detector according to an embodiment of the present disclosure.

### DETAILED DESCRIPTION

The present disclosure will be described hereinafter in conjunction with the drawings and embodiments. The following embodiments are for illustrative purposes only, but shall not be used to limit the scope of the present disclosure. Actually, the embodiments are provided so as to facilitate the understanding of the scope of the present disclosure.

Unless otherwise defined, such words as “one” or “one of” are merely used to represent the existence of at least one member, rather than to limit the number thereof. Such words as “include” or “including” intend to indicate that there are the features, integers, steps, operations, elements and/or assemblies, without excluding the existence or addition of one or more other features, integers, steps, operations, elements, assemblies and/or combinations thereof. In addition, the expression “and/or” is used to indicate the existence of all or any one of one or more of listed items, or combinations thereof.

Unless otherwise defined, any technical or scientific term used herein shall have the common meaning understood by a person of ordinary skills. Any term defined in a commonly-used dictionary shall be understood as having the meaning in conformity with that in the related art, shall not be interpreted idealistically and extremely.

FIG. 1 shows a structure of a X-ray flat panel detector in related art. As shown in FIG. 1, as a body structure, the X-ray flat panel detector includes a substrate 1, a thin film transistor arranged on the substrate 1, a photodiode 9 juxtaposed with the thin film transistor, and a scintillation layer (not shown) arranged above the photodiode 9. The thin film transistor includes a gate electrode 3, a gate insulation layer 4, an active layer 5 and a source/drain electrode layer 6. The photodiode 9 includes a P-type semiconductor layer, an N-type semiconductor layer, and an intrinsic semiconductor layer arranged between the P-type semiconductor layer and the N-type semiconductor layer. A first electrode 8 is connected to a drain electrode of the thin film transistor, and a second electrode 10 is arranged on the photodiode 9. In addition, a buffer layer 2 is arranged between the substrate 1 and the thin film transistor, and a protection layer (not shown) is arranged on the second electrode 10.

A working principle of the X-ray flat panel detector will be described as follows. An X-ray is modulated by a human body on a transmission path of the X-ray, and the modulated X-ray is converted by the scintillation layer into visible light. The visible light is absorbed by the photodiode and converted into charge carriers, and the charge carriers are stored in a storage capacitor or a capacitor of the photodiode itself to form image charges. The thin film transistors are turned on progressively through an external scanning control circuitry, and the image charges are read simultaneously by the thin film transistors in each row and outputted to an external data processing circuitry. The image charges read by each thin film transistor corresponds to a dose of an incident X-ray, and the image charges are processed by the external data processing circuitry to determine an amount of charges for each pixel point, thereby to determine a dose of the X-ray for each pixel point.

However, it is found that, due to an insufficient evenness of a film layer above a projection of the thin film transistor, with a level difference of above 5000 Å, so during the design of pixels, an active photosensitive part of the photodiode is provided with an insufficient area to cover the thin film transistor. In other words, in the related art, the thin film transistor is juxtaposed with the photodiode, so a filling rate of the flat panel detector is seriously adversely affected by this design mode, thereby a resolution and detection performance of the X-ray flat panel detector are adversely affected.

In addition, it is found that, when a back plate layer (including such film layers as the thin film transistor) has a relatively large size and a detection surface of the X-ray flat panel detector has a relatively small area, it is necessary to manufacture the back plate layer with a small size, so as to match the photodiode with a small size, thereby to meet the requirement on the detection surface of the X-ray flat panel detector. In the related art, it is impossible for the back plate layer to be compatible with the photodiodes with different sizes, so the manufacture cost may increase. In addition, a yield of the back plate layer may be adversely affected to some extent.

An object of the present disclosure is to provide a new X-ray flat panel detector and a method for manufacturing the X-ray flat panel detector, so as to solve the problems in the related art where the X-ray flat panel detector has a low resolution when a filling rate is restrained by a size of the thin film transistor and a metal wiring, and the manufacture cost of the X-ray flat panel detector is relatively high.

The X-ray flat panel detector in the embodiments of the present disclosure will be described in more details hereinafter in conjunction with the drawings.

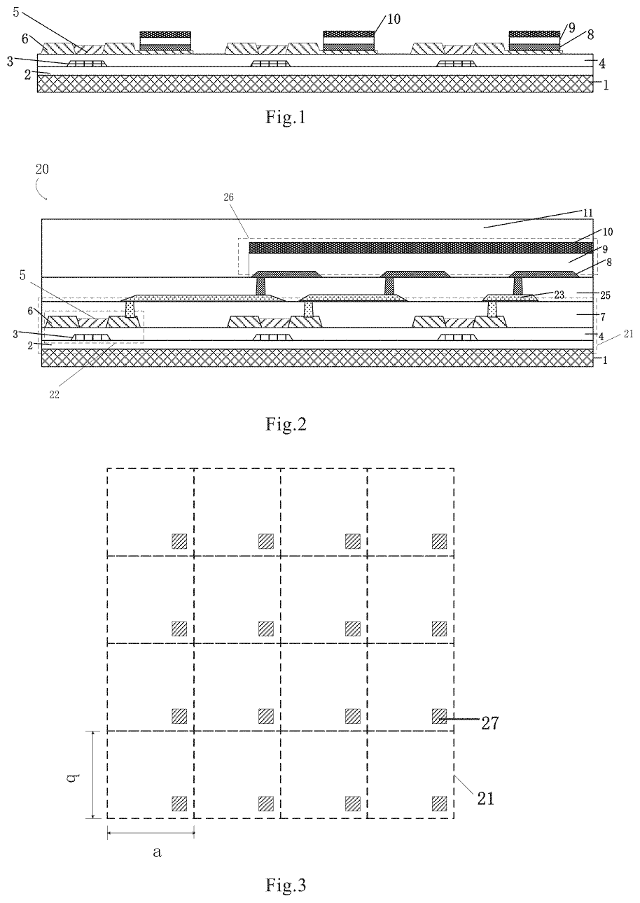

The present disclosure provides in some embodiments an X-ray flat panel detector 20 which, as shown in FIG. 2, includes a substrate 1, a back plate layer 21, a wiring layer and a photosensitive element layer 26. The back plate layer 21 is arranged on the substrate 1, and includes a plurality of thin film transistors 22. Each thin film transistor 22 includes a gate electrode 3, a gate insulation layer 4, an active layer 5 and a source/drain electrode layer 6. The wiring layer is arranged at a side of the back plate layer 21 distal to the substrate 1, and includes a plurality of connection lines 23 and a planarization layer 25. The photosensitive element layer 26 is arranged at a side of the wiring layer distal to the substrate 1, and includes a plurality of first electrodes 8. Each first electrode 8 is electrically connected to the source/drain electrode layer 6 of a corresponding thin film transistor 22 through a corresponding connection line 23, and an orthogonal projection of each first electrode 8 onto the substrate 1 does not overlap an orthogonal projection of the corresponding thin film transistor 22 onto the substrate 1.

Because the photosensitive element layer 26 of the X-ray flat panel detector 20 in the embodiments of the present disclosure is arranged at a side of the wiring layer distal to the substrate 1 and the wiring layer is arranged at a side of the back plate layer 21 distal to the substrate 1, the photosensitive element layer 26 and the back plate layer 21 are arranged sequentially in a direction perpendicular to the substrate 1. As compared with the related art where the thin film transistor is juxtaposed with the photosensitive element layer, in the embodiments of the present disclosure, the design of the photosensitive element layer 26 is not adversely affected by the thin film transistor 22, so it is able to increase a filling rate of the X-ray flat panel detector 20, thereby to increase a resolution and detection performance of the X-ray flat panel detector 20. In addition, in the embodiments of the present disclosure, each first electrode 8 is electrically connected to the source/drain electrode layer 6 of the corresponding thin film transistor 22 through the corresponding connection line 23, and the orthogonal projection of the first electrode 8 onto the substrate 1 does not overlap the orthogonal projection of the corresponding thin film transistor 22 onto the substrate 1. Through the arrangement of the connection lines 23, an orthogonal projection of each pixel in the back plate layer 21 onto the substrate 1 does not overlap an orthogonal projection of a corresponding pixel in the photosensitive element layer 26 onto the substrate 1, so it is able to further increase the resolution of the X-ray flat panel detector 20, thereby to enable the X-ray flat panel detector to be applied to a high-resolution application scenario, e.g., for the detection of mammary gland and industrial detection. Further, through the arrangement of the connection lines, it is able for the large-size back plate layer 21 to be compatible with the small-size photosensitive element layer 26, thereby to reduce the manufacture cost.

It should be appreciated that, the thin film transistor 22 in the embodiments of the present disclosure is an amorphous-silicon thin film transistor, an oxide thin film transistor, a low-temperature poly-silicon thin film transistor, or an organic transistor. In addition, the thin film transistor 22 is a top-gate thin film transistor, a side-gate thin film transistor or a bottom-gate thin film transistor.

In a possible embodiment of the present disclosure, as shown in FIG. 2, an area of an orthogonal projection of the photosensitive element layer 26 onto the substrate 1 is smaller than an area of an orthogonal projection of the back plate layer 21 onto the substrate 1. Due to the arrangement of the connection lines 23, each thin film transistor 22 is electrically connected to the photosensitive element layer 26 through the corresponding connection line 23, and a position of the orthogonal projection of the photosensitive element layer 26 onto the substrate 1 is changed through the connection line 23. In the embodiments of the present disclosure, the area of the orthogonal projection of the photosensitive element layer 26 onto the substrate 1 is smaller than the area of the orthogonal projection of the back plate layer 21 onto the substrate 1, so in the case of a small detection area, i.e., when the photosensitive element layer 26 has a small size, it is able for the large-size back plate layer 21 to match the small-size photosensitive element layer 26 through the connection lines 23, without any necessity to manufacture the small-size back plate layer 21 separately, thereby to reduce the manufacture cost. It should be noted that, in actual design, the area of the orthogonal projection of the photosensitive element layer 26 onto the substrate 1 may be alternatively greater than the area of the orthogonal projection of the back plate layer 21 onto the substrate 1, so as to be adapted to different detection areas.

During the implementation, the X-ray flat panel detector in the embodiments of the present disclosure is a mammary gland flat panel detector which is usually used for previous diagnosis of breast cancer. In order to find any tiny calcified points in the mammary gland, a current detection member has a pixel size of 50 μm to 75 μum, but the back plate layer connected to the detection member has a pixel size of 140 μm. According to the X-ray flat panel detector in the embodiments of the present disclosure, through the arrangement of the connection lines 23, the orthogonal projection of the pixel in the back plate layer 21 onto the substrate does not overlap the orthogonal projection of the pixel in the photosensitive element layer 26 (i.e., the detection member) onto the substrate, so it is able for each pixel in the large-size back plate layer to be connected to a corresponding pixel in the small-size photosensitive element layer 26, thereby to provide the X-ray flat panel detector with a high resolution.

In a possible embodiment of the present disclosure, as shown in FIGS. 2 and 3, the back plate layer 21 includes a passivation layer 7 arranged at a side of the thin film transistor 22 distal to the substrate 1 and covering the substrate 1, a plurality of first via-holes 27 is formed in the passivation layer 7, a source electrode or a drain electrode of each thin film transistor 22 is exposed through a corresponding first via-hole 27, and each connection line 23 is electrically connected to a source electrode or a drain electrode of a corresponding thin film transistor 22 through a corresponding first via-hole 27.

FIG. 3 shows the arrangement of the first via-holes 27 penetrating through the passivation layer 7. As shown in FIG. 3, the back plate layer 21 includes first spaces arranged in an array form, each first space corresponds to one pixel in the back plate layer 21, and one first via-hole 27 is formed in each first space. To be specific, each first space has a first length a and a first width b, e.g., each of the first length a and the first width b is 140 μm.

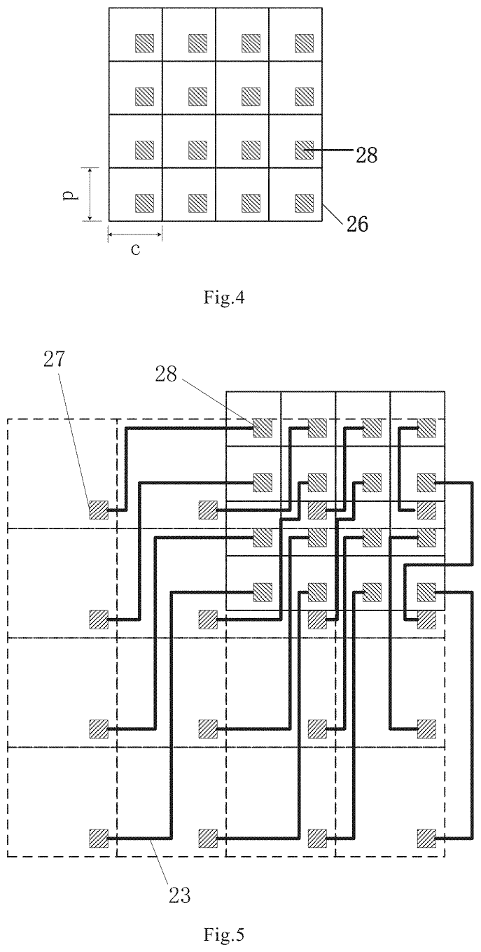

In a possible embodiment of the present disclosure, as shown in FIGS. 2 and 4, the wiring layer includes a planarization layer 25 arranged at a side of the photosensitive element layer 26 proximate to the substrate 1 and covering the connection lines 23, a plurality of second via-holes 28 is formed in the planarization layer 25 at predetermined positions, and each first electrode 8 is electrically connected to a corresponding connection line 23 through a corresponding second via-hole 28. Here, the predetermined position is a position where the first electrode 8 needs to be connected to the corresponding connection line 23, and it is set according to the practical need. Through the arrangement of the planarization layer 25, it is able to prevent the occurrence of a level difference for the film layer at a position where the thin film transistor 22 is located, and provide an even film layer above the projection of the thin film transistor 22. In this regard, the photosensitive element layer 26 and the back plate layer 21 are arranged sequentially in the direction perpendicular to the substrate 1, so as to increase the filling rate of the X-ray flat panel detector 20, thereby to improve the resolution and the detection performance of the X-ray flat panel detector 20.

FIG. 4 shows the arrangement of the second via-holes 28 penetrating through the planarization layer 25. As shown in FIG. 4, the photosensitive element layer 26 includes a plurality of second spaces arranged in an array form, each second space corresponds to one pixel in the photosensitive element layer 26, and a respective one second via-hole 28 is formed in each second space. To be specific, each second space has a second length c and a second width d, e.g., each of the second length c and the second width d is 70 μm. The value of each of the second length c and the second width d is set in such a manner as to meet the requirement on a small pixel in the detection of mammary gland and the industrial detection, but an area of each second space may also be modified according to the practical need.

In a possible embodiment of the present disclosure, the photosensitive element layer 26 is arranged in any of four corner regions of the substrate 1. As shown in FIG. 5, the photosensitive element layer 26 is arranged in an upper right corner of the substrate 1. It should be noted that, in actual design, the photosensitive element layer 26 may alternatively arranged at a lower right corner, an upper left corner or a lower left corner of the substrate 1. In another possible embodiment of the present disclosure, the photosensitive element layer 26 may alternatively be arranged in a middle region of the substrate 1. A specific position of the photosensitive element layer 26 on the substrate 1 is set according to the practical need, which will thus not be particularly defined herein.

In a possible embodiment of the present disclosure, as shown in FIG. 2, the photosensitive element layer 26 includes a photodiode 9 and a second electrode 10, the photodiode 9 is arranged at a side of the first electrode 8 distal to the substrate 1, and the second electrode 10 is arranged at a side of the photodiode 9 distal to the first electrode 8. To be specific, in the embodiments of the present disclosure, the first electrode 8 is made of molybdenum (Mo), and a thickness of the first electrode 8 in the direction perpendicular to the substrate 1 is 2200 Å. The second electrode 10 is made of a same material as the first electrode 8, and a thickness of the second electrode 10 in the direction perpendicular to the substrate 1 is 1350 Å. The photodiode 9 includes a P-type semiconductor layer, an N-type semiconductor layer, and an intrinsic semiconductor layer arranged between the P-type semiconductor layer and the N-type semiconductor layer.

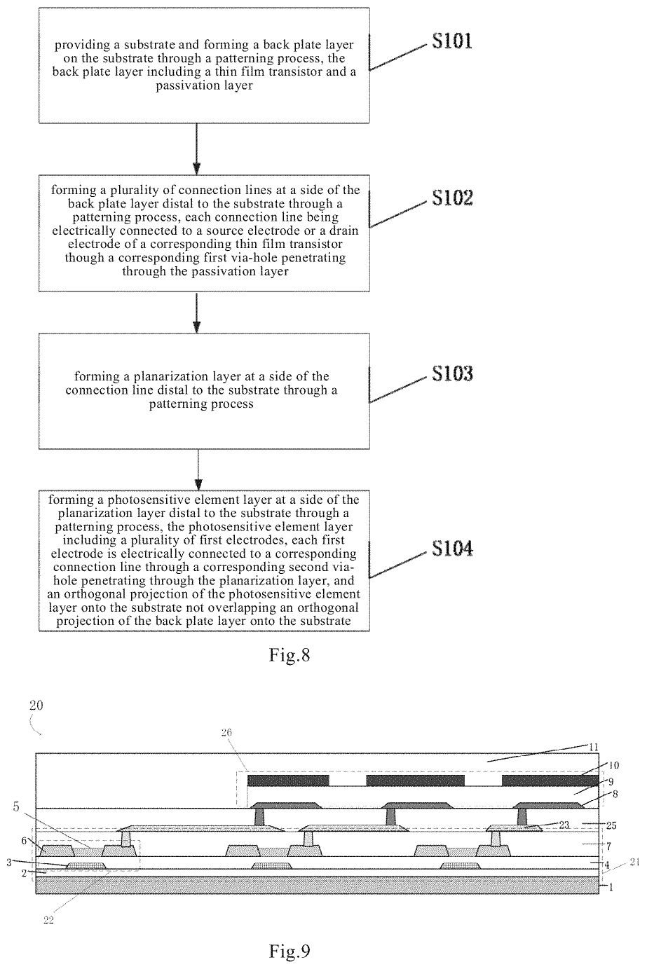

In a possible embodiment of the present disclosure, as shown in FIG. 2, the first electrode 8 is a bar-shaped electrode and the second electrode 10 is a planar electrode; or as shown in FIG. 9, the first electrode 8 is a bar-shaped electrode, the second electrode 10 is a bar-shaped electrode too, and an orthogonal projection of the second electrode 10 onto the substrate 1 covers an orthogonal projection of the first electrode 8 onto the substrate 1.

In a possible embodiment of the present disclosure, as shown in FIG. 2, in order to further protect the photosensitive element layer 26, the X-ray flat panel detector 20 further includes a protection layer 11 arranged at a side of the photosensitive element layer 26 distal to the substrate 1 and covering the substrate 1. An area of an orthogonal projection of the protection layer 11 onto the substrate 1 is greater than the area of the orthogonal projection of the photosensitive element layer 26 onto the substrate 1.

Based on a same inventive concept, the present disclosure further provides in some embodiments an X-ray flat panel detection device, which includes a plurality of the above-mentioned X-ray flat panel detectors 20 arranged in an array form. Adjacent X-ray flat panel detectors 20 are spliced with each other, and the photosensitive element layer 26 is arranged proximate to a position where the adjacent X-ray flat panel detectors are spliced. The X-ray flat panel detection device includes the above-mentioned X-ray flat panel detector 20, so it has a same beneficial effect as the X-ray flat panel detector 20, which will thus not be particularly defined herein.

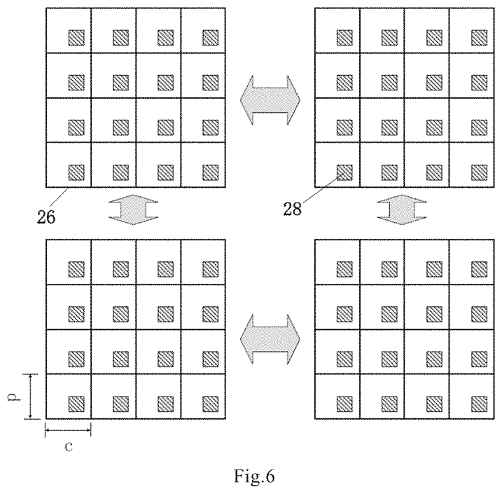

In actual use, in order to increase a detection area of the X-ray flat panel detector 20 and enable the back plate layer to be compatible with the photosensitive element layers 26 with different sizes, in the embodiments of the present disclosure, the photosensitive element layers 26 may be designed in a spliced manner. As shown in FIG. 6, four small-size photosensitive element layers 26 are spliced to form a large-size photosensitive element layer.

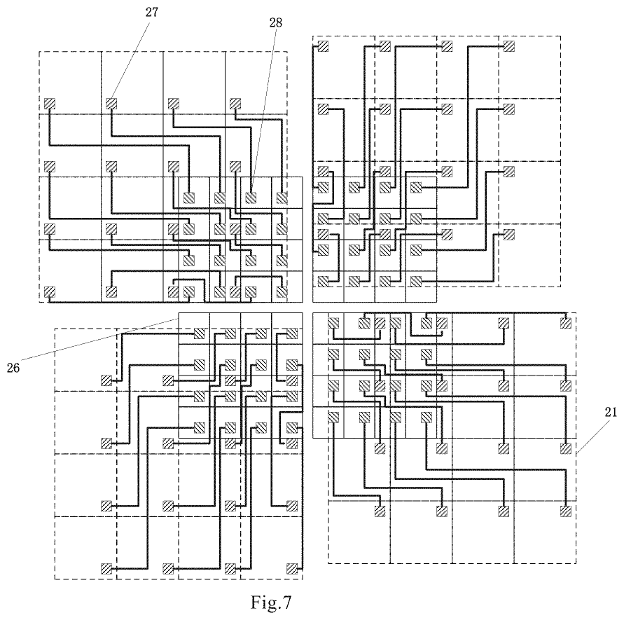

To be specific, as shown in FIG. 7 which shows a situation where the adjacent X-ray flat panel detectors 20 are connected to each other in a spliced manner, the photosensitive element layer 26 is arranged proximate to a splicing position, i.e., located in a middle region of the entire X-ray flat panel detection device. The photosensitive element layer 26 is arranged at a corner region of each individual X-ray flat panel detector 20. According to the X-ray flat panel detection device acquired after splicing, it is able to further improve the resolution without adversely affecting the design of the connection lines.

Based on a same inventive concept, the present disclosure further provides in some embodiments an X-ray imaging system, which includes the above-mentioned X-ray flat panel detector 20 or the above-mentioned X-ray flat panel detection device. Because the X-ray imaging system includes the above-mentioned X-ray flat panel detector 20 or the above-mentioned X-ray flat panel detection device, it has a same beneficial effect as the above-mentioned X-ray flat panel detector 20 or the above-mentioned X-ray flat panel detection device, which will thus not be particularly further defined herein.

Based on a same inventive concept, the present disclosure further provides in some embodiments a method for manufacturing the X-ray flat panel detector 20 which, as shown in FIG. 8, includes: S101 of providing the substrate 1 and forming the back plate layer 21 on the substrate 1 through a patterning process, the back plate layer 21 including the thin film transistor 22 and the passivation layer 7; S102 of forming a plurality of connection lines 23 at a side of the back plate layer 21 distal to the substrate 1 through a patterning process, each connection line 23 being electrically connected to a source electrode or a drain electrode of a corresponding thin film transistor 22 though a corresponding first via-hole 27 penetrating through the passivation layer 7; S103 of forming the planarization layer 25 at a side of the connection line 23 distal to the substrate 1 through a patterning process; and S104 of forming the photosensitive element layer 26 at a side of the planarization layer 25 distal to the substrate 1 through a patterning process. The photosensitive element layer 26 includes a plurality of first electrodes 8, each first electrode 8 is electrically connected to a corresponding connection line 23 through a corresponding second via-hole 28 penetrating through the planarization layer 25, and an orthogonal projection of each first electrode 8 onto the substrate 1 does not overlap an orthogonal projection of the thin film transistor 22 of the back plate layer 21 whose source electrode or drain electrode is electrically connected to the first electrode 8 onto the substrate 1.

Because the X-ray flat panel detector 20 in the embodiments of the present disclosure is provided with the planarization layer 25, the photosensitive element layer 26 and the back plate layer 21 are arranged sequentially in a direction perpendicular to the substrate 1. As compared with the related art where the thin film transistor is juxtaposed with the photosensitive element layer, in the embodiments of the present disclosure, the design of the photosensitive element layer 26 is not adversely affected by the thin film transistor 22, so it is able to increase a filling rate of the X-ray flat panel detector 20, thereby to increase a resolution and detection performance of the X-ray flat panel detector 20. In addition, in the embodiments of the present disclosure, each first electrode 8 of the photosensitive element layer 26 is electrically connected to one connection line 23 through the corresponding second via-hole 28 in the planarization layer 25, so an orthogonal projection of each pixel in the back plate layer 21 onto the substrate 1 does not overlap an orthogonal projection of a corresponding pixel in the photosensitive element layer 26 onto the substrate 1. As a result, it is able to further increase the resolution of the X-ray flat panel detector 20, thereby to enable the X-ray flat panel detector to be applied to a high-resolution application scenario, e.g., for the detection of mammary gland and industrial detection. Further, through the arrangement of the connection lines, it is able for the large-size back plate layer 21 to be compatible with the small-size photosensitive element layer 26, thereby to reduce the manufacture cost.

In a possible embodiment of the present disclosure, the forming the back plate layer 21 on the substrate 1 through a patterning process includes: forming 1 buffer layer 2 on the substrate 1; forming a gate electrode 3, a gate insulation layer 4, an active layer 5, a source electrode and a drain electrode sequentially on the buffer layer 2 through a patterning process; and forming the passivation layer 7 on the source electrode and the drain electrode through a patterning process.

During the implementation, the forming the passivation layer 7 on the source electrode and the drain electrode through a patterning process includes coating an insulation film layer onto the source electrode and the drain electrode, and patterning the insulation film layer to form the passivation layer 7. The plurality of first via-holes 27 is formed in the passivation layer 7.

In a possible embodiment of the present disclosure, the forming the plurality of connection lines 23 at a side of the back plate layer 21 distal to the substrate 1 through a patterning process includes: depositing a metal layer, e.g., an aluminum (Al) or copper (Cu) layer, on the passivation layer 7; and patterning the metal layer to form the plurality of connection lines 23. An orthogonal projection of each connection line 23 onto the substrate 1 covers an orthogonal projection of a corresponding first via-hole 27 onto the substrate 1 and an orthogonal projection of a corresponding second via-hole 28 onto the substrate 1. To be specific, as shown in FIG. 2, each connection line 23 formed after patterning needs to extend to the corresponding first via-hole 27 and the corresponding second via-hole 28, so that one end of the connection line 23 is capable of being connected to the source electrode or drain electrode of the thin film transistor 22 and the other end is capable of being connected to the corresponding first electrode 8.

In a possible embodiment of the present disclosure, the forming the photosensitive element layer 26 at a side of the planarization layer 25 distal to the substrate 1 through a patterning process includes: forming the plurality of first electrodes 8 on the planarization layer 25 through a patterning process, each first electrode 8 being electrically connected to a corresponding connection line 23 through a corresponding second via-hole 28 in the planarization layer 25; forming the photodiode 9 on each first electrode 8 through a patterning process; and forming the second electrode 10 on each photodiode 9 through a patterning process.

During the implementation, the forming the photodiode 9 on the first electrode 8 through a patterning process includes forming an N-type semiconductor layer, an intrinsic semiconductor layer and a P-type semiconductor layer sequentially in that order on the first electrode 8 through a patterning process.

The present disclosure has the following beneficial effects.

1. Because the photosensitive element layer 26 of the X-ray flat panel detector 20 in the embodiments of the present disclosure is arranged at a side of the wiring layer distal to the substrate 1 and the wiring layer is arranged at a side of the back plate layer 21 distal to the substrate 1, the photosensitive element layer 26 and the back plate layer 21 are arranged sequentially in a direction perpendicular to the substrate 1. As compared with the related art where the thin film transistor is juxtaposed with the photosensitive element layer, in the embodiments of the present disclosure, the design of the photosensitive element layer 26 is not adversely affected by the thin film transistor 22, so it is able to increase a filling rate of the X-ray flat panel detector 20, thereby to increase a resolution and detection performance of the X-ray flat panel detector 20. In addition, in the embodiments of the present disclosure, each first electrode 8 is electrically connected to the source/drain electrode layer 6 of the corresponding thin film transistor 22 through the corresponding connection line 23, and the orthogonal projection of the first electrode 8 onto the substrate 1 does not overlap the orthogonal projection of the corresponding thin film transistor 22 onto the substrate 1. Through the arrangement of the connection lines 23, an orthogonal projection of each pixel in the back plate layer 21 onto the substrate 1 does not overlap an orthogonal projection of a corresponding pixel in the photosensitive element layer 26 onto the substrate 1, so it is able to further increase the resolution of the X-ray flat panel detector 20, thereby to enable the X-ray flat panel detector to be applied to a high-resolution application scenario, e.g., for the detection of mammary gland and industrial detection. Further, through the arrangement of the connection lines, it is able for the large-size back plate layer 21 to be compatible with the small-size photosensitive element layer 26, thereby to reduce the manufacture cost.

2. The X-ray flat panel detection device in the embodiments of the present disclosure includes a plurality of the above-mentioned X-ray flat panel detectors 20. The adjacent X-ray flat panel detectors 20 are spliced with each other, and the photosensitive element layer 26 is arranged proximate to a splicing position. Through this arrangement, it is able to increase a detection area of the X-ray flat panel detector, thereby to further improve the resolution, and enable the back plate layer to be compatible with the photosensitive element layers 26 with different sizes.

It should be appreciated that, steps, measures and schemes in various operations, methods and processes that have already been discussed in the embodiments of the present disclosure may be replaced, modified, combined or deleted. In a possible embodiment of the present disclosure, the other steps, measures and schemes in various operations, methods and processes that have already been discussed in the embodiments of the present disclosure may also be replaced, modified, rearranged, decomposed, combined or deleted. In another possible embodiment of the present disclosure, steps, measures and schemes in various operations, methods and processes that are known in the related art and have already been discussed in the embodiments of the present disclosure may also be replaced, modified, rearranged, decomposed, combined or deleted.

It should be further appreciated that, such words as “center”, “on”, “under”, “front”, “back”, “left”, “right”, “vertical”, “horizontal”, “top”, “bottom”, “inner” and “outer” are used to indicate directions or positions as viewed in the drawings, and they are merely used to facilitate the description in the present disclosure, rather than to indicate or imply that a device or member must be arranged or operated at a specific position.

In addition, such words as “first” and “second” may merely be adopted to differentiate different features rather than to implicitly or explicitly indicate any number or importance, i.e., they may be adopted to implicitly or explicitly indicate that there is at least one said feature. Further, such a phrase as “a plurality of” may be adopted to indicate that there are two or more features, unless otherwise specified.

The above embodiments are for illustrative purposes only, but the present disclosure is not limited thereto. Obviously, a person skilled in the art may make further modifications and improvements without departing from the principle of the present disclosure, and these modifications and improvements shall also fall within the scope of the present disclosure.

What is claimed is:

1. An X-ray flat panel detector, comprising:
a substrate;
a back plate layer arranged on the substrate and comprising a plurality of thin film transistors, each of the thin film transistors comprising a source/drain electrode layer;
a wiring layer arranged at a side of the back plate layer distal to the substrate and comprising a plurality of connection lines; and
a photosensitive element layer arranged at a side of the wiring layer distal to the substrate and comprising a plurality of first electrodes,
wherein each of the first electrodes is electrically connected to the source/drain electrode layer of a respective one of the thin film transistors through a respective one of the connection lines, and an orthogonal projection of the first electrode onto the substrate does not overlap an orthogonal projection of the respective thin film transistor onto the substrate.

2. The X-ray flat panel detector according to claim 1, wherein an area of an orthogonal projection of the photosensitive element layer onto the substrate is smaller than an area of an orthogonal projection of the back plate layer onto the substrate.

3. The X-ray flat panel detector according to claim 2, wherein the back plate layer comprises a passivation layer;
the passivation layer is arranged at a side of the thin film transistor distal to the substrate and covers the substrate, a plurality of first via-holes is formed in the passivation layer and penetrates through the passivation layer, each of the first via-holes exposes a source electrode or a drain electrode of a respective one of the thin film transistors;
each of the connection lines is electrically connected to a source electrode or a drain electrode of a respective one of the thin film transistor through the respective first via-hole.

4. The X-ray flat panel detector according to claim 2, wherein the wiring layer comprises a planarization layer, the planarization layer is arranged at a side of the photosensitive element layer proximate to the substrate and covers the connection lines, a plurality of second via-holes is formed in the planarization layer at predetermined positions and penetrates through the planarization layer;
each of the first electrodes is electrically connected to a respective one of the connection lines through a respective one of the second via-hole.

5. The X-ray flat panel detector according to claim 2, wherein the photosensitive element layer comprises a photodiode and a second electrode;
the photodiode is arranged at a side of the first electrode distal to the substrate;
the second electrode is arranged at a side of the photodiode distal to the first electrode.

6. The X-ray flat panel detector according to claim 5, wherein the first electrode is a bar-shaped electrode, and the second electrode is a planar electrode; or
the first electrode is a bar-shaped electrode, the second electrode is a bar-shaped electrode, and an orthogonal projection of the second electrode onto the substrate covers an orthogonal projection of the first electrode onto the substrate.

7. The X-ray flat panel detector according to claim 1, further comprising a protection layer, wherein the protection layer is arranged at a side of the photosensitive element layer distal to the substrate and covers the substrate;
an area of an orthogonal projection of the protection layer onto the substrate is greater than an area of the orthogonal projection of the photosensitive element layer onto the substrate.

8. An X-ray flat panel detection device, comprising a plurality of the X-ray flat panel detectors according to claim 1 and arranged in an array form;
adjacent ones of the X-ray flat panel detectors are spliced with each other, and the photosensitive element layer is arranged proximate to a position where the adjacent X-ray flat panel detectors are spliced.

9. The X-ray flat panel detection device according to claim 8, wherein an area of an orthogonal projection of the photosensitive element layer onto the substrate is smaller than an area of an orthogonal projection of the back plate layer onto the substrate.

10. The X-ray flat panel detection device according to claim 9, wherein the back plate layer comprises a passivation layer;
the passivation layer is arranged at a side of the thin film transistor distal to the substrate and covers the substrate, a plurality of first via-holes is formed in the passivation layer and penetrates through the passivation layer, each of the first via-holes exposes a source electrode or a drain electrode of a respective one of the thin film transistors;
each of the connection lines is electrically connected to a source electrode or a drain electrode of a respective one of the thin film transistor through the respective first via-hole.

11. The X-ray flat panel detection device according to claim 9, wherein the wiring layer comprises a planarization layer, the planarization layer is arranged at a side of the photosensitive element layer proximate to the substrate and covers the connection lines, a plurality of second via-holes is formed in the planarization layer at predetermined positions and penetrates through the planarization layer;
each of the first electrodes is electrically connected to a respective one of the connection lines through a respective one of the second via-hole.

12. The X-ray flat panel detection device according to claim 11, wherein the photosensitive element layer comprises a photodiode and a second electrode;
the photodiode is arranged at a side of the first electrode distal to the substrate;
the second electrode is arranged at a side of the photodiode distal to the first electrode.

13. The X-ray flat panel detection device according to claim 12, wherein the first electrode is a bar-shaped electrode, and the second electrode is a planar electrode; or
the first electrode is a bar-shaped electrode, the second electrode is a bar-shaped electrode, and an orthogonal projection of the second electrode onto the substrate covers an orthogonal projection of the first electrode onto the substrate.

14. The X-ray flat panel detection device according to claim 8, wherein the X-ray flat panel detector further comprises a protection layer, wherein the protection layer is arranged at a side of the photosensitive element layer distal to the substrate and covers the substrate;
an area of an orthogonal projection of the protection layer onto the substrate is greater than an area of the orthogonal projection of the photosensitive element layer onto the substrate.

15. An X-ray imaging system comprising the X-ray flat panel detector according to claim 1.

16. An X-ray imaging system, comprising the X-ray flat panel detection device according to claim 8.

17. A method for manufacturing an X-ray flat panel detector, comprising:
providing a substrate, and forming a back plate layer on the substrate through a patterning process, wherein the back plate layer comprises thin film transistors and a passivation layer;
forming a plurality of connection lines at a side of the back plate layer distal to the substrate through a patterning process, wherein each of the connection lines is electrically connected to a source electrode or a drain electrode of a respective one of the thin film transistors through a respective first via-hole, the first via-hole penetrates through the passivation layer;
forming a planarization layer at a side of the connection line distal to the substrate through a patterning process; and
forming a photosensitive element layer at a side of the planarization layer distal to the substrate through a patterning process,
wherein the photosensitive element layer comprises a plurality of first electrodes, each of the first electrodes is electrically connected to a respective one of the connection lines through a respective second via-hole, the second via-hole penetrates through the planarization layer, and an orthogonal projection of the first electrode onto the substrate does not overlap an orthogonal projection of a thin film transistor whose source electrode or drain electrode is electrically connected to the first electrode onto the substrate.

18. The method according to claim 17, wherein the forming the back plate layer on the substrate through the patterning process comprises:
forming a buffer layer on the substrate;
forming a gate electrode, a gate insulation layer, an active layer, a source electrode and a drain electrode sequentially on the buffer layer through a patterning process; and
forming the passivation layer on the source electrode and the drain electrode through a patterning process.

19. The method according to claim 18, wherein the forming the plurality of connection lines at the side of the back plate layer distal to the substrate through the patterning process comprises:
depositing a metal layer on the passivation layer; and
patterning the metal layer to form the plurality of connection lines,
wherein an orthogonal projection of each of the connection lines onto the substrate covers an orthogonal projection of the first via-hole onto the substrate and an orthogonal projection of the second via-hole onto the substrate.

20. The method according to claim 17, wherein the forming the photosensitive element layer at the side of the planarization layer distal to the substrate through the patterning process comprises:
forming the plurality of first electrodes on the planarization layer through a patterning process, wherein each of the first electrodes is electrically connected to a respective one of the connection lines through the respective second via-hole penetrating through the planarization layer;
forming a photodiode on the first electrode through a patterning process;
forming a second electrode on each photodiode through a patterning process.
